(19) United States
(12) Patent Application Publication
(10) Pub. No.: US 2026/0136592 A1
(43) Pub. Date: May 14, 2026

(54) OXIDE SEMICONDUCTOR CHANNEL STACK

(71) Applicant: ZINITE CORPORATION, Vancouver (CA)

(72) Inventors: Gem SHOUTE, Edmonton (CA); Douglas BARLAGE, Edmonton (CA); Alex MA, Edmonton (CA)

(21) Appl. No.: 18/853,088

(22) PCT Filed: Jun. 4, 2024
(86) PCT No.: PCT/IB2024/055451

§ 371 Date: Sep. 30, 2024

Related U.S. Application Data
(60) Provisional application No. 63/471,094, filed on Jun. 5, 2023.

(51) Int. Cl. H10D 30/67; H10D 30/01

(52) U.S. Cl. CPC H10D 30/6704; H10D 30/0314; H10D 30/6731; H10D 30/6755

(57) ABSTRACT

A oxide semiconductor channel stack for semiconductor devices having an oxide semiconductor channel layer, an optional mediating material layer formed over the oxide semiconductor channel layer and a setting layer formed over the mediating material layer, if present, or over the oxide semiconductor channel layer. The setting layer draws surplus oxygen atoms from an adjacent region of the oxide semiconductor to reduce defects therein, thus increasing the current carrying capacity through a channel formed in the oxide semiconductor channel layer. The setting layer can also serve as a contact, such as a gate contact, or a separate metal layer can be formed over the setting layer to serve as a contact.

### FIELD OF THE INVENTION

The present invention relates to semiconductor devices. More specifically, the present invention relates to an oxide semiconductor channel stack for, and a method of producing such a stack in, semiconductor devices which provide enhanced current carrying ability.

### BACKGROUND OF THE INVENTION

Semiconductor devices with oxide semiconductor channels, such as CMOS transistors, Thin Film Transistors (TFTs), etc. are well known. As such devices are widely employed in a variety of use cases with differing needs, a variety of oxide semiconductor channel stacks are used in these devices and a variety of manufacturing processes are known to produce them.

With at least some of these semiconductor devices, the current carrying capacity of the oxide semiconductor channel stack is a limiting factor in the performance of circuits employing the semiconductor devices.

It is desired to have an oxide semiconductor channel stack, and method of manufacturing that channel stack, which provides improved current carrying capacity of semiconductor devices with oxide semiconductor channels.

### SUMMARY OF THE INVENTION

It is an object of the present invention to provide a novel oxide semiconductor channel stack, and a method of manufacturing that stack, which obviates or mitigates at least one disadvantage of the prior art.

According to a first aspect of the present invention, there is provided an oxide semiconductor channel stack comprising: an oxide semiconductor channel layer; a setting layer formed over the oxide semiconductor channel layer, the setting layer drawing undesired atoms from a region of the oxide semiconductor channel layer adjacent the setting layer to reduce defects therein. Preferably, the setting layer is selected from the group comprising: titanium; hafnium; zirconium; and/or tantalum. Also preferably, the oxide semiconductor channel layer is selected from the group comprising zinc oxide, tin oxide and/or indium gallium zinc oxide.

According to another aspect of the present invention, there is provided a method of forming an oxide semiconductor stack, comprising the steps of: forming an oxide semiconductor channel layer on a substrate; and forming a setting material over the oxide semiconductor channel layer to draw undesired atoms from a region of the oxide semiconductor metal member adjacent the setting material.

According to yet another aspect of the present invention, there is provided a thin film transistor comprising: a substrate; a source formed on the substrate; a drain formed on the substrate and spaced from the source; a source channel interfacial member formed on the source; an oxide semiconductor channel layer formed on the substrate extending between and connecting the source channel interfacial member and the drain; a mediating layer comprising a gate dielectric formed over the oxide semiconductor channel layer; and a setting material comprising a metal gate contact formed over the mediating layer, the setting material drawing undesired atoms from a region of the oxide semiconductor channel layer adjacent the setting material to reduce defects therein.

### BRIEF DESCRIPTION OF THE DRAWINGS

Preferred embodiments of the present invention will now be described, by way of example only, with reference to the attached Figures, wherein:

FIG. 1 shows a cross section of a prior art oxide semiconductor channel stack;

FIG. 2 shows a cross section of an oxide semiconductor channel stack including a layer of a setting layer in accordance with an aspect of the present invention;

FIG. 3 shows the cross section of FIG. 2 with a depiction of a region of the oxide semiconductor channel stack affected by the setting layer;

FIG. 4 shows a cross section of a thin film transistor employing an oxide semiconductor stack in accordance with an aspect of the present invention; and

FIG. 5 shows a cross section of an oxide semiconductor channel stack similar to that of FIG. 2 but where a mediating layer has been omitted;

FIG. 6 shows a flowchart of a process to manufacture an oxide semiconductor stack in accordance with an aspect of the present invention.

### DETAILED DESCRIPTION OF THE INVENTION

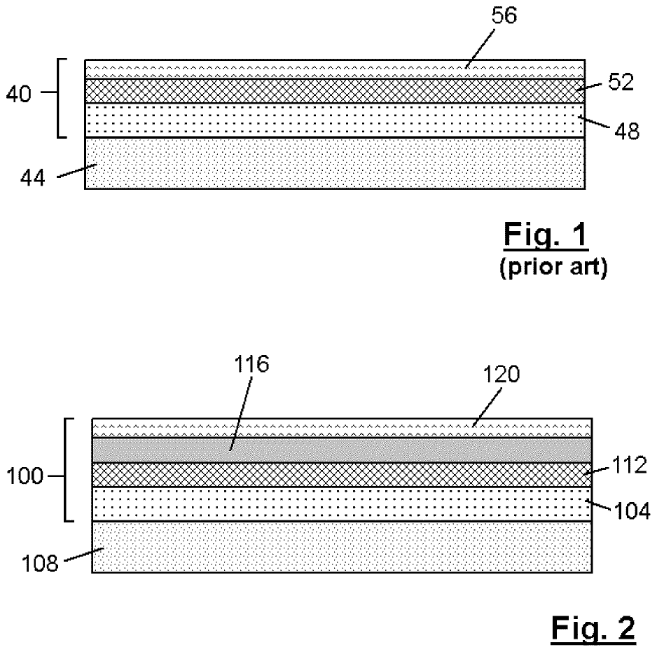

As an example of a prior art oxide semiconductor channel stack, a field effect transistor (FET) has an oxide semiconductor channel stack, illustrated schematically at 40, in FIG. 1. As shown, stack 40 is formed on a substrate 44, which can be any of a variety of insulating or dielectric materials such as silicon dioxide, etc.

Stack 40 includes an oxide semiconductor channel layer 48, such as zinc oxide (ZnO), indium gallium zinc oxide (IGZO), tin oxide (SnO₂), etc. which, in this example, is formed on substrate 44. A layer of dielectric material is formed over oxide semiconductor channel layer 48 to serve as a gate dielectric 52 and a layer of metal is formed on gate dielectric 52 to serve as a gate 56.

Not shown in FIG. 1 are the source and drain (or emitter and base) electrodes which are connected by stack 40 and which, together with gate 56, form a transistor, such as a thin film transistor (TFT). As is well known, when a voltage above a determined level (e.g.—Vₒₙ) is applied to gate 56, a conducting channel forms in oxide semiconductor channel layer 48 and electrical current can flow, from the source to the drain, through the resulting channel. The selection of appropriate channel materials, dielectrics, gate metals, etc. in stack 40 are all within the normal purview of those of skill in the art.

While semiconductor devices employing oxide semiconductor channel stacks, such as stack 40, are well known and widely employed, their electrical current carrying capacity can be less than desired. In particular, defects in oxide semiconductor channel layer 48, such as excess oxygen or the presence of various contaminates, impede carrier mobility, and thus current flow, through the channel formed in channel layer 48, thus limiting the current carrying capacity of the channel.

FIG. 2 shows a novel oxide semiconductor channel stack 100, in accordance with an aspect of the present invention. Stack 100 includes an oxide semiconductor channel layer 104 which is formed on a dielectric layer 108 which can be a substrate, such as silicon dioxide, plastic, glass, etc. or which can be a dielectric layer over another semiconductor device (in the case of 3D “stacked” layers of transistors), etc.

In stack 100, non-limiting examples of oxide semiconductor channel layer 104 can include: zinc oxide (ZnO), indium gallium zinc oxide (IGZO), tin oxide (SnO₂), etc., as well as nitrogen-fixed oxide semiconductors such as SnON, ZnON, etc., or doped oxide semiconductors such as Al—ZnO, Ta-doped SnO₂, etc.

A mediating material 112, such as a layer of low-k dielectric, high-k dielectric, or semiconductor, etc., is formed on oxide semiconductor channel layer 104 and mediating material 112 can be a gate dielectric, sacrificial dielectric (removed in subsequent processing) or another semiconductor device element as desired, as it is contemplated that stack 100 can be employed in a variety of semiconductor devices including, but not limited to: CMOS transistors; TFTs; bipolar junction transistors (BJTs); heterojunction bipolar transistor (HBTs), etc.

The present inventors have determined that a significant factor leading to current carrying limitations in oxide semiconductor channel layer 104, and leading to reduced carrier mobility/current flow through a channel formed therein, is the presence of surplus oxygen atoms, undesired materials and/or contaminates, such as nitrogen, carbon, chlorine, fluorine, etc. in oxide semiconductor channel layer 104. Such undesired materials can be general contaminates and/or can inadvertently be Introduced during various manufacturing processes.

For example, if oxide semiconductor channel layer 104 is tin oxide (SnO₂), such as when channel stack 100 forms part of a TFT, the default stoichiometry for the desired crystalline structure of the oxide semiconductor material is 1:2 (one tin atom to two oxygen atoms).

Defects occur in oxide semiconductor channel layer 104 when surplus oxygen atoms are present, increasing the stoichiometric ratio to 1:2.1, 1:2.2, etc., and these defects inhibit carrier mobility/current flow. Similarly, defects occur in semiconductor channel layer 104 if undesired nitrogen, carbon, chlorine, fluorine, etc. atoms and/or other contaminates are introduced to semiconductor channel layer 104 during manufacturing or are otherwise present.

Accordingly, in stack 100 a setting layer 116 is formed over mediating material 112. In some implementations, setting layer 116 is a metal which will also serve as a gate contact, while in other implementations, such as that illustrated in FIG. 2, a gate contact 120 is formed over setting layer 166. In both implementations, setting layer 116 is selected to attract oxygen and/or contaminate atoms and functions to attract such undesired atoms through mediating material 112 out of at least the region of oxide semiconductor channel layer 104 adjacent mediating material 112 and setting layer 116. Hence, setting layer 116 acts to “set” the stoichiometry of this region of the material of oxide semiconductor channel layer 104.

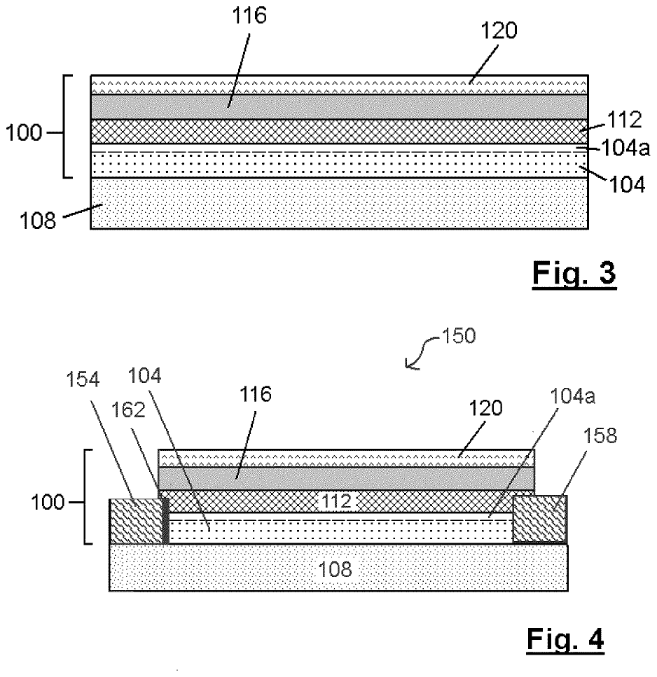

FIG. 3 shows a (not to scale) representation of the result of forming setting layer 116 between metal contact layer 120 and mediating material 112, namely the formation of a region 104a within oxide semiconductor channel layer 104 where surplus oxygen and/or other undesired atoms have been drawn out. Region 104a has a decreased number of defects, thus improving carrier mobility/current flow through the channel therein.

Setting layer 116 is a metal with a negative reduction potential, i.e.—a metal to which oxygen and/or other undesired atoms have a strong affinity/attraction. Ideally, metal contact layer 120 is selected to, in addition to acting as a contact, inhibit the ingress of oxygen and/or other atoms into setting layer 116 from above.

It is also contemplated that, as mentioned above, depending upon the intended use and requirements of stack 100, mediating material 112 can be sacrificial. In such cases, mediating material 112 and setting layer 116 are selected for their ability to remove undesired atoms from region 104a and mediating material 112 and setting layer 116 are removed, after the setting process has occurred, and a replacement mediating layer 112 selected for its desired properties (such as to serve as a gate dielectric) and a metal setting layer 116, selected for its desired properties (such as to serve as a gate contact) are reformed over region 104a of oxide semiconductor channel layer 104.

One example of a specific stack 100 for a TFT is illustrated in FIG. 4. In FIG. 4, a TFT 150, such as that described in published PCT patent application WO 2023/285936 to Barlage et al. and assigned to the assignee of the present invention (and the contents of which are incorporated herein by reference) is shown. TFT 150 includes a source 154, a drain 158, each of which can be a suitable metal, such as Ruthenium, etc. and a source channel interfacial member 162, such as Ruthenium Oxide. Stack 100 includes oxide semiconductor channel layer 104 which can be tin oxide (SnO₂), mediating material 112 which can be hafnium oxide, acting as a gate dielectric, metal contact layer 120 can be tungsten, tantalum nitride or titanium nitride, acting as a gate contact and, in this example, setting layer 116 can be titanium.

The respective layers of stack 100 can be formed in any suitable manner as will occur to those of skill in the art, such as by atomic layer deposition (ALD), sputtering, CVD, PECVD, etc.

In the above-mentioned example of the Barlage et al TFT, oxide semiconductor channel layer 104 can be formed as a layer of between about 3 nm and about 15 nm thick and more preferably, a layer of between about 5 nm and about 10 nm thick. Setting layer 116 can be formed in any suitable manner, such as by sputtering or chemical vapor deposition, as a layer between about 1 nm and about 10 nm thick.

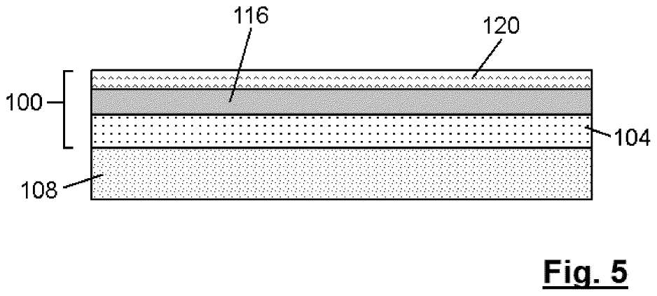

It is also contemplated that, in some circumstances, mediating material 112 can be omitted, as shown in FIG. 5 (wherein like components to those to FIG. 2 are indicated with like reference numerals) with setting layer 116 in direct contact with oxide semiconductor channel layer 104, but in most cases, mediating material 112 is preferably present and can be between about 1 nm to about 20 nm thick.

It is contemplated that setting layer 116 should not be excessively thick as it is possible that it can otherwise draw too many oxygen atoms from oxide semiconductor channel layer 104, reducing its stoichiometry from 1:2 to 1:1.6 or 1:1.5, etc., potentially changing it from a semiconductor to a conductor.

In the example described herein, setting layer 116 can have a thickness of from about 0.2 nm to about 3 nm to draw surplus oxygen atoms from region 104a of oxide semiconductor channel layer 104, thus reducing defects in region 104a. Region 104a can be from about 2 nm to as much as the entire thickness of semiconductor channel layer 104.

In tests of TFTs fabricated with novel stack 100, measurements of carrier mobility have shown as much as a ten times improvement over that that of similar TFTs fabricated without the presence of setting layer 116.

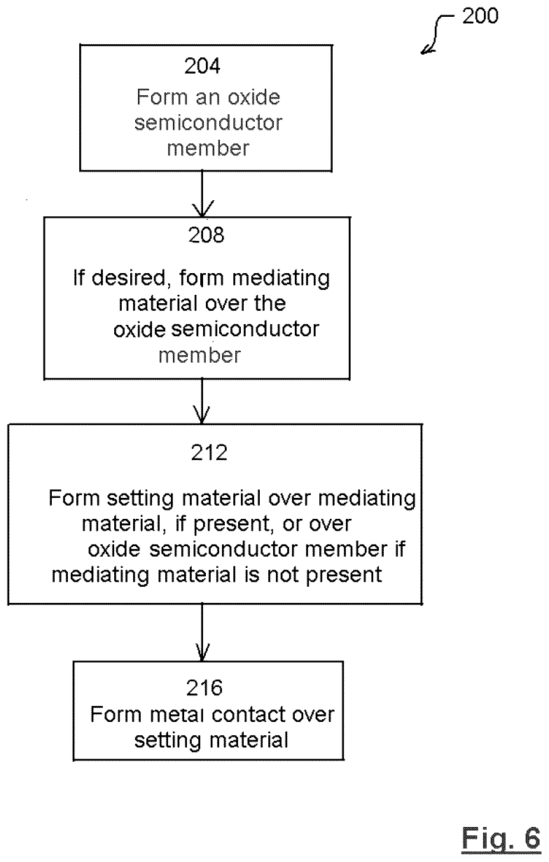

As shown in FIG. 6, a method 200 of fabricating an oxide semiconductor channel stack, in accordance with an aspect of the present invention comprises the steps of: at 204 forming an oxide semiconductor channel layer on a substrate; at 208, if desired, forming a mediating material over the oxide semiconductor channel layer; at step 212, forming a setting material over the mediating material, if present, or over the oxide semiconductor channel layer if the mediating material is not present, the setting material removing undesired atoms from at least the region of oxide semiconductor channel layer adjacent the setting material; and at 216, if desired, forming a metal contact over the setting material.

Non limiting examples of suitable setting materials include Titanium, Hafnium, Zirconium and/or Tantalum.

Non limiting examples of suitable mediating materials, if present, include low-k dielectrics, high-k dielectrics, semiconductors, etc.

The above-described embodiments of the invention are intended to be examples of the present invention and alterations and modifications may be effected thereto, by those of skill in the art, without departing from the scope of the invention which is defined solely by the claims appended hereto.

We claim:

1. An oxide semiconductor channel stack comprising:
an oxide semiconductor channel layer;
a setting layer formed over the oxide semiconductor channel layer, the setting layer drawing undesired atoms from a region of the oxide semiconductor channel layer adjacent the setting layer to reduce defects therein.

2. The oxide semiconductor channel stack of claim 1 wherein the setting layer has a negative reduction potential.

3. The oxide semiconductor channel stack of claim 2 wherein the setting layer is selected from the group comprising: titanium; hafnium; zirconium; or tantalum.

4. The oxide semiconductor channel stack of claim 1 wherein the oxide semiconductor channel layer is tin oxide and the setting layer is titanium.

5. The oxide semiconductor channel stack of claim 1 wherein the oxide semiconductor channel layer is a nitrogen-fixed metal oxide.

6. The oxide semiconductor channel stack of claim 1 wherein the oxide semiconductor channel layer is a layer of tin oxide having a thickness of from about 3 nm to about 15 nm.

7. The oxide semiconductor channel stack of claim 1 wherein the oxide semiconductor channel layer is a layer of tin oxide having a thickness of from about 5 nm to about 10 nm.

8. The oxide semiconductor channel stack of claim 1 wherein the undesired atoms include oxygen atoms and the region of oxide semiconductor channel layer from which the oxygen atoms are drawn has a thickness of from about 2 nm to the entire thickness of the oxide semiconductor layer.

9. The oxide semiconductor channel stack of claim 1 further including a mediating layer formed between the oxide semiconductor channel layer and the setting layer.

10. The oxide semiconductor channel stack of claim 9 wherein the mediating layer is a gate dielectric and the setting layer is a gate contact.

11. A method of forming an oxide semiconductor stack, comprising the steps of:
forming an oxide semiconductor channel layer on a substrate; and
forming a setting material over the oxide semiconductor channel layer to draw undesired atoms from a region of the oxide semiconductor channel layer adjacent the setting material.

12. The method of claim 11 further comprising the step of forming a layer of mediating material between the oxide semiconductor channel layer and the setting material.

13. The method of claim 12 wherein the mediating material is a gate dielectric and the setting material is a gate contact.

14. The method of claim 12 wherein, once undesired atoms have been drawn from the region of the oxide semiconductor channel layer, the mediating material and setting material are removed from the oxide semiconductor stack and are replaced with a gate dielectric and a gate contact respectively.

15. The method of claim 11 further including the step of forming a metal layer over the setting material layer.

16. A thin film transistor comprising:
a substrate;
a source formed on the substrate;
a drain formed on the substrate and spaced from the source;
a source channel interfacial member formed on the source;
an oxide semiconductor channel layer formed on the substrate extending between and connecting the source channel interfacial member and the drain;
a mediating layer comprising a gate dielectric formed over the oxide semiconductor channel layer; and
a setting material comprising a metal gate contact formed over the mediating layer, the setting material drawing undesired atoms from a region of the oxide semiconductor channel layer adjacent the setting material to reduce defects therein.

17. The thin film transistor of claim 16 wherein the undesired atoms include surplus oxygen atoms.

18. The thin film transistor according to claim 16 wherein the undesired atoms include contaminates.

19. The thin film transistor according to claim 16 wherein the setting material is a metal selected from the group comprising: titanium; hafnium; zirconium; and/or tantalum.
